(19) United States
(12) Patent Application Publication
(10) Pub. No.: US 2013/0109180 A1
(43) Pub. Date: May 2, 2013

(54) METHOD FOR POLISHING SILICON WAFER, AND POLISHING SOLUTION FOR USE IN THE METHOD

(71) Applicants: Ryuichi Tanimoto, Tokyo (JP); Shinichi Ogata, Tokyo (JP); Isamu Gotou, Tokyo (JP); Kenji Yamashita, Tokyo (JP); Masahiro Asari, Tokyo (JP)

(72) Inventors: Ryuichi Tanimoto, Tokyo (JP); Shinichi Ogata, Tokyo (JP); Isamu Gotou, Tokyo (JP); Kenji Yamashita, Tokyo (JP); Masahiro Asari, Tokyo (JP)

(73) Assignee: SUMCO CORPORATION, Tokyo (JP)

(21) Appl. No.: 13/805,463

(22) PCT Filed: Jul. 6, 2011
(86) PCT No.: PCT/JP2011/065476

§ 371 Date: Dec. 19, 2012

(30) Foreign Application Priority Data
Jul. 8, 2010 (JP) 2010-155329

(51) Int. Cl. H01L 21/306

(52) U.S. Cl. CPC H01L 21/30625
USPC 438/692; 252/79.1

(57) ABSTRACT

A to-be-polished surface of a silicon wafer is rough polished while supplying to a hard polishing cloth a polishing solution in which a water-soluble polymer has been added to an alkaline aqueous solution having free abrasive grains. Thus, polishing at a high polishing rate and roll-off on an outer periphery of the wafer can be satisfied simultaneously.

### FIELD OF THE INVENTION

The present invention relates to a method for polishing a silicon wafer and a polishing solution for the method. More specifically, the present invention relates to a method for polishing a silicon wafer and a polishing solution for the method in which the silicon wafer and a polishing cloth are rotated relative to each other while the polishing solution is supplied to polish at least a front surface of the front and rear surfaces of the silicon wafer as a polished surface, the polishing solution containing free abrasive grains in an alkaline aqueous solution.

### BACKGROUND OF THE INVENTION

In recent years, CMP (chemical-mechanical polishing) has been common as a method for polishing a front surface of a silicon wafer. CMP is performed by rotating the silicon wafer and a polishing cloth relative to each other while supplying a polishing solution, in which an alkaline aqueous solution contains free abrasive grains such as silica grains. CMP is known for obtaining a high degree of flatness for a front surface of the silicon wafer by combining a mechanical polishing effect from the free abrasive grains with a chemical polishing effect from the alkaline aqueous solution. In the CMP process for the silicon wafer, typically, polishing is performed through a plurality of steps, from rough polishing to finish polishing.

Rough polishing, the earliest step, seeks to polish the silicon wafer to a desired thickness. A polishing cloth of a hard material such as hardened urethane resin is used with a comparatively high polishing speed to polish the silicon wafer so as to reduce and flatten variations in the thickness of the silicon wafer after polishing. In the rough polishing operation, the polishing process may be performed while breaking the polishing amount (stock amount) of the silicon wafer into a plurality of stages (e.g., stages one to three) and changing the type of polishing cloth and the size of the free abrasive grains. Finish polishing, the last step, is performed to remedy roughness on the front surface of the silicon wafer. A pliant polishing cloth such as suede is used with minute free abrasive grains to polish the silicon wafer so as to reduce minute variations in surface roughness such as micro-roughness and haze on the front surface of the silicon wafer. Similar to the rough polishing operation, the finish polishing operation may be broken into a plurality of stages while changing the type of polishing cloth and the size of the free abrasive grains.

From the perspective of device miniaturization in recent years and expanding a range of device forms for the silicon wafer, a high degree of flatness is required even in a vicinity of the outermost periphery of the silicon wafer, thus heightening concern for flatness in the vicinity of the outermost periphery and a surface deformation amount of the wafer. Accordingly, in order to evaluate a shape of the outermost periphery of the silicon wafer, an index called ROA (Roll-Off Amount) is known which quantitatively expresses an amount of drop and an amount of rise on the outer periphery of the wafer.

An imaginary standard flat surface is obtained from a wafer shape, for example, at a position (reference area) 124 mm-135 mm from the center of a silicon wafer having a diameter of 300 mm that is believed to be flat. ROA 1 mm, for example, is then defined as a distance to a position 1 mm from an outer edge of the wafer toward an interior. At this point, a height of the standard flat surface is defined as 0. When a shape up to the outer edge of the wafer drops below this, an amount of displacement has a −value (roll-off). When a shape rises instead, the amount of displacement has a +value (roll-up). In addition, the smaller the absolute value of the roll-off and roll-up, the higher the degree of flatness is evaluated to be, even at the outermost periphery.

The amount of polishing the silicon wafer receives in the rough polishing operation is typically greater than in the finish polishing operation. Thus, viscoelasticity of the polishing cloth has a large effect and there is a negative circumstance in which the outer periphery of the wafer may be excessively polished, which may cause roll-off to develop in the silicon wafer after rough polishing. Therefore, in the invention recited in Related Art 1, for example, a method for double surface polishing is suggested in which a carrier plate having a thickness greater than the thickness of the silicon wafer before polishing is used. The silicon wafer is accommodated within the carrier plate, then the carrier plate is sandwiched between an upper platen and a lower platen to which polishing cloths have been adhered. In this state, the front and rear surfaces of the silicon wafer are simultaneously polished.

When polishing the front and back surfaces of the silicon wafer so as to achieve a wafer thickness equal to or less than the thickness of the carrier plate, the carrier plate inhibits the polishing of the outer periphery of the wafer by the polishing cloths. Thus, the amount of roll-off that develops is indeed reduced. However, in the invention recited in Related Art 1, when the carrier plate presses into the polishing cloth, the polishing cloth is lifted up in a portion positioned at a wafer holding aperture of the carrier plate (i.e., at the wafer held in the wafer holding aperture). The lifted polishing cloth makes strong contact with the outer periphery of the wafer, and as a result the outer periphery of the wafer is polished. Therefore, the advantageous effect of reducing roll-off is insufficient. Additional issues include the carrier plate itself being polished, thus increasing a replacement frequency for the carrier plate and causing production costs to rise, or the carrier plate vibrating due to being polished, thus causing the silicon wafer to jump out of the carrier plate during the polishing process.

### RELATED ART

### Patent Literature

Related Art 1: Japanese Patent Laid-open Publication No. 2005-158798

### SUMMARY OF THE INVENTION

### Problems to Be Solved by the Invention

In view of the above-described circumstance of roll-off developing in the silicon wafer during the rough polishing operation, and as a result of thorough research, the inventors have found that in rough polishing of a front surface of a silicon wafer, when the front surface of the wafer is polished using a hard polishing cloth such as polyurethane while supplying a polishing solution in which a water-soluble polymer has been added to an alkaline aqueous solution containing free abrasive grains, a high polishing rate can be maintained and, by adjusting a concentration of the water-soluble polymer added to the polishing solution, an outer periphery of the silicon wafer can be made into a shape without roll-off, thus achieving the present invention.

The present invention has as an object to provide a method for polishing a silicon wafer and a polishing solution for the method which is capable of polishing a polished surface of the silicon wafer at a high polishing rate and also of preventing roll-off in an outer periphery of the silicon wafer.

### Means for Solving the Problems

The invention of claim 1 is a method for polishing a silicon wafer, in which the silicon wafer and a hard polishing cloth are rotated relative to each other while a polishing solution is supplied to the polishing cloth to rough polish at least a front surface of the front and rear surfaces of the silicon wafer as a polished surface, the polishing solution having a water-soluble polymer added to an alkaline aqueous solution containing free abrasive grains.

The invention of claim 2 is the method for polishing the silicon wafer according to claim 1, in which the water-soluble polymer is one kind or several kinds among a non-ionic polymer and a monomer, or one kind or several kinds among an anionic polymer and a monomer.

The invention of claim 3 is the method for polishing the silicon wafer according to claim 2, in which the water-soluble polymer is hydroxyethylcellulose.

The invention of claim 4 is the method for polishing the silicon wafer according to claim 3, in which a concentration of hydroxyethylcellulose in the polishing solution is 1 ppm-200 ppm.

The invention of claim 5 is the method for polishing the silicon wafer according to claim 1, in which a content amount of an alkaline agent in the alkaline aqueous solution is 100-1000 ppm. The alkaline aqueous solution is an alkaline aqueous solution to which any of a basic ammonium salt, a basic potassium salt, and a basic sodium salt has been added as the alkaline agent; an alkaline carbonate aqueous solution; or an alkaline aqueous solution to which amine has been added.

The invention of claim 6 is the method for polishing the silicon wafer according to claim 1, in which the polishing cloth is composed of a non-woven fabric made from polyester, or is made from polyurethane.

The invention of claim 7 is the method for polishing the silicon wafer according to claim 1, in which the rough polishing simultaneously polishes the front and rear surfaces of the silicon wafer with a double surface polishing device that includes a carrier plate accommodating the silicon wafer which has not yet been rough polished, and an upper platen having the polishing cloth adhered to a bottom surface thereof and a lower platen having a separate polishing cloth adhered to a top surface thereof, the upper and lower platen sandwiching the carrier plate from above and below.

The invention of claim 8 is the method for polishing the silicon wafer according to claim 7, in which the silicon wafer is polished such that a thickness of the silicon wafer after rough polishing is greater than the thickness of the carrier plate.

The invention of claim 9 is a polishing solution used during rough polishing at least a front surface of the front and rear surfaces of a silicon wafer as a polished surface, the polishing solution having as a chief component an alkaline aqueous solution containing free abrasive grains and having a water-soluble polymer added to the alkaline aqueous solution.

The invention of claim 10 is the polishing solution according to claim 9, in which a content amount of an alkaline agent in the alkaline aqueous solution is 100-1000 ppm. The alkaline aqueous solution is an alkaline aqueous solution to which any of a basic ammonium salt, a basic potassium salt, and a basic sodium salt has been added as the alkaline agent; an alkaline carbonate aqueous solution; or an alkaline aqueous solution to which amine has been added. The water-soluble polymer is one kind or several kinds among a non-ionic polymer and a monomer, or one kind or several kinds among an anionic polymer and a monomer.

The invention of claim 11 is the polishing solution according to claim 10, in which the water-soluble polymer is hydroxyethylcellulose.

The invention of claim 12 is the polishing solution according to claim 11, in which a concentration of hydroxyethylcellulose in the alkaline aqueous solution is adjusted to be in a concentration range of 1 ppm-200 ppm.

### Effect of the Invention

According to the method for polishing the silicon wafer and the polishing solution of the present invention, a reduction of roll-off in an outer periphery of the wafer can be achieved while maintaining a high polishing rate and, in addition, control can be achieved over a degree of flatness (ROA) for the outer periphery of the wafer that includes roll-off and roll-up. Furthermore, development of processing damage and development of processing-induced defects such as micro-scratches arising from an aggregation of abrasive grains can be reduced.

### BRIEF DESCRIPTION OF THE DRAWINGS

FIG. 1 is a perspective view of a non-sun gear-type double surface polishing device used in a method for polishing a silicon wafer in a first embodiment according to the present invention.

FIG. 2 is a vertical cross-sectional view of a relevant portion of the non-sun gear-type double surface polishing device used in the method for polishing the silicon wafer in the first embodiment according to the present invention.

FIG. 3 is a graph illustrating an outer peripheral shape of the silicon wafer according to an additive rate of a water-soluble polymer for the silicon wafer which has been polished by the method for polishing the silicon wafer in the first embodiment according to the present invention.

### MODE FOR CARRYING OUT THE INVENTION

A method for polishing a silicon wafer in the present invention is a method for polishing a silicon wafer in which the silicon wafer and a hard polishing cloth are rotated relative to each other while a polishing solution is supplied to the polishing cloth to rough polish a polished surface of the silicon wafer, the polishing solution having a water-soluble polymer added to an alkaline aqueous solution containing free abrasive grains.

According to the method for polishing the silicon wafer in the present invention, due to an etching effect from the alkaline aqueous solution, an abrasion effect from the free abrasive grains, and an etching inhibition effect on an outer periphery of the silicon wafer from the water-soluble polymer, roll-off on the outer periphery of the wafer can be prevented while maintaining a high polishing rate. In addition, conventional polishing methods use a polishing solution in which no water-soluble polymer is present despite including the free abrasive grains. As the polishing progresses, roll-off on the outer periphery of the wafer is promoted. In contrast, in the case of the present invention, due to the etching inhibition effect on the outer periphery of the silicon wafer from the water-soluble polymer described above, by having a long polishing time and increasing a polishing amount, for example, the outer periphery of the wafer can be made to have a roll-up shape. Thus, assuming roll-off on the outer periphery of the wafer during finish polishing, for example, an ideal flat shape can be achieved for the outer periphery of the wafer.

Moreover, the reason that roll-off is prevented (decreased) is conjectured to be due to an occurrence of a phenomenon described below. During the polishing process, the water-soluble polymer in the polishing solution is adsorbed into the front surface of the silicon wafer and the front surface of the wafer becomes coated by the water-soluble polymer. The free abrasive grains in the polishing solution receive pressure from the polishing cloth (rotation of the polishing platens) and pressure from the silicon wafer (rotation of the silicon wafer). Thereby, the free abrasive grains actively flow and make contact with the wafer, then flow to an exterior of the polished surface while adsorbing the polymer film formed on the polished surface (surface to be polished) of the silicon wafer. The polished surface from which the polymer film has been stripped is reactive, and thus is chemically etched by the alkaline aqueous solution. Polishing is believed to be advanced through repetition of this adsorption of the water-soluble polymer, stripping of the polymer layer, alkali etching, and abrasion from the free abrasive grains. Meanwhile, the water-soluble polymer adheres to an edge (chamfered portion) of the unpolished silicon wafer, as well. However, the probability is extremely low that the polymer film adsorbed to this portion will be stripped by the free abrasive grains. The etching reaction on the outer periphery of the wafer is inhibited by the water-soluble polymer film adsorbed to the edge of the silicon wafer, and the amount of roll-off is theorized to be reduced thereby.

In the method for polishing the silicon wafer in the present invention, the alkaline aqueous solution containing the free abrasive grains is used as the polishing solution. Herein, “the alkaline aqueous solution containing the free abrasive grains” means a polishing solution in which, for example, free abrasive grains such as colloidal silica (abrasive grains), diamond abrasive grains, and alumina abrasive grains are mixed into the alkaline aqueous solution which is the chief component of the polishing solution. By including the free abrasive grains, the polymer film adhered to the polished surface can be effectively stripped and the etching effect from the alkaline aqueous solution on the front surface of the silicon wafer can be heightened. In addition, a natural oxide film of around 5-20 Å is typically present on the front surface of the silicon wafer before the rough polishing operation due to an early stage cleaning process or exposure to a highly pure atmosphere. However, by including the free abrasive grains, rough polishing can be performed while stripping the oxide film. Therefore, there is no need to include an operation to strip the oxide film with an etching process using a chemical solution such as hydrofluoric acid. Moreover, the average particle size of the free abrasive grains used is preferably 30-200 nm. Use of free abrasive grains with an average particle size of 50-150 nm is particularly preferred. At an average particle size of less than 30 nm, the abrasive grains aggregate and processing-induced defects such as micro-scratches are likely to be triggered. At more than 200 nm, colloidal dispersion becomes difficult and variations in concentration arise.

The content amount of the alkaline agent in the alkaline aqueous solution is 100-1000 ppm. At less than 100 ppm, the etching force of the alkaline agent on the front surface of the silicon wafer is insufficient and a long period of time is required to polish the silicon wafer to a desired thickness. At more than 1000 ppm, handling of the polishing solution itself becomes difficult and surface roughness becomes more likely to develop on the front surface of the wafer due to an excessive etching reaction. An alkaline aqueous solution to which any of a basic ammonium salt, a basic potassium salt, and a basic sodium salt has been added; an alkaline carbonate aqueous solution; or an alkaline aqueous solution to which amine has been added, for example, are the alkaline agent (pH adjusting agent) of the alkaline aqueous solution. In addition, a hydrazine or amine aqueous solution may be used. From the perspective of increasing the polishing rate, an alkali other than ammonia is preferred, and use of an amine is particularly preferred.

Anionics and their ampholytes and each non-ionic polymer and monomer and the like may be used as the water-soluble polymer. Specifically, hydroxyethylcellulose or polyethylene glycol are preferably used as the water-soluble polymer. In particular, highly pure hydroxyethylcellulose can be obtained comparatively easily and readily forms the polymer film on the front surface of the wafer. Thus, the effect of inhibiting the etching reaction from the alkali is characteristically high. However, of the various kinds of water-soluble polymer, a water-soluble polymer that promotes the etching of the silicon wafer by the alkaline aqueous solution is unsuitable. One kind of the water-soluble polymer may be used, or a plurality of kinds may be used.

In addition, instead of the water-soluble polymer, a surfactant or a fatty alcohol may be used. Polyoxyethylene alkyl ether or the like may be used, for example, as the surfactant. Polyvinyl alcohol or the like may be used, for example, as the fatty alcohol.

The concentration of the water-soluble polymer in the polishing solution may be set to a concentration range of 1 ppm-200 ppm, and 100 ppm or less is particularly preferred. When hydroxyethylcellulose is used as the water-soluble polymer, the additive rate is preferably 100 ppm or less. When an excessive amount of the water-soluble polymer is added, the polishing rate of the silicon wafer is greatly reduced and productivity is reduced.

A monocrystalline silicon wafer or a polycrystalline silicon wafer, for example, may be employed as the silicon wafer. The diameter of the silicon wafer may be, for example, 100 mm, 125 mm, 150 mm, 200 mm, 300 mm, and 450 mm.

A hard polishing cloth is used as the polishing cloth for the rough polishing. A reduction in the amount of roll-off on the outer periphery of the silicon wafer can thus be achieved. Specifically, the polishing process is conducted with the silicon wafer pressed against the polishing cloth. Therefore, should a pliant polishing cloth be used, the silicon wafer will sink into the polishing cloth and a reactive force of the polishing cloth attempting to return to an original form has a large effect at the outer periphery of the wafer. The water-soluble polymer film adsorbed to the outer periphery of the silicon wafer is thus aggressively stripped away and roll-off is likely to develop. When a hard polishing cloth is used, recession into the polishing cloth is slight, and thus the water-soluble polymer adsorbed to the edge of the unpolished silicon wafer can be maintained while the water-soluble polymer adsorbed to the polished surface of the silicon wafer can be efficiently removed. A high polishing rate and large roll-off inhibition effect can thus be achieved simultaneously.

A polishing cloth having a Shore A hardness of 70-90 and an elastic compression modulus of 0.5-5%, and in particular 2-4%, as defined by JIS K 6253-1997/ISO 7619 is preferably used as the hard polishing cloth. At less than a Shore A hardness of 70, the polishing rate increases for a region up to 3 mm from the outer peripheral edge of the silicon wafer and roll off is likely to develop on the outer periphery of the wafer. When the Shore A hardness is more than 90, polishing flaws may become more likely to develop on the front surface of the wafer.

Specific examples of the hard polishing cloth include a polishing cloth composed of a non-woven fabric made from polyester and a polishing cloth made from polyurethane. In particular, a polishing cloth made of foamed polyurethane, which has excellent mirror surfacing accuracy for the polished surface of the silicon wafer, is preferred. When using a polishing cloth made of suede, which is pliant and readily conforms to an outer peripheral shape of the silicon wafer, as is used in finish polishing, etching at the outer periphery of the wafer is promoted and roll-off occurs.

The rough polishing is performed by rotating the silicon wafer and the polishing cloth relative to each other. “Rotating relative to each other” means rotating the silicon wafer, rotating the polishing cloth, or rotating both the silicon wafer and the polishing cloth. Rotation directions of the silicon wafer and the polishing cloth are at the user's discretion. For example, when both the silicon wafer and the polishing cloth are rotated, the rotation direction of the two may be the same or different. However, when the rotation direction is the same, the rotation speed must be different.

The polishing rate of the silicon wafer during the rough polishing is preferably 0.05-1 μm/minute. At less than 0.05 μm/minute, the polishing rate is low and polishing requires a long time. When greater than 1 μm/minute, surface roughness is likely to occur on the front surface of the silicon wafer due to an increased concentration of alkali and an increased additive rate of the free abrasive grains. The rotation speed of the silicon wafer, the rotation speed of the polishing cloth, polishing pressure, and the like may be set so as to be within the range for the polishing rate described above. For example, the rotation speed for each of the silicon wafer and the polishing cloth may be selected from within a range of 5-100 rpm, and the polishing pressure may be set within a range of 30-500 g/cm². Moreover, the polishing amount in the rough polishing may be set in consideration of the desired thickness of the silicon wafer, and is set within an overall range of 1 μm-20 μm. The amount of polishing in the finish polishing, which is performed after the rough polishing, may be set within a range of 1 μm or less.

In the rough polishing of the silicon wafer, a single wafer type polishing device may be used, or a batch type polishing device in which a plurality of silicon wafers are polished simultaneously may be used. Single surface polishing of only the front surface or double surface polishing in which the front surface and rear surface of the wafer are polished simultaneously may be used. In particular, when rough polishing the front and rear surfaces of the wafer simultaneously, polishing is preferably performed using a double surface polishing device that includes a carrier plate accommodating the silicon wafer and an upper platen and lower platen to which polishing cloths have been adhered, on either side of the carrier plate. A high degree of flatness can thus be achieved for the rear surface of the wafer, not only the front surface of the wafer, in a single polishing process, which is effective in providing mirror-surfaced silicon wafers having a high degree of flatness at low cost.

When performing double surface polishing of the front and rear surfaces of the silicon wafer using the polishing solution that contains free abrasive grains, the silicon wafer is preferably polished such that the thickness of the silicon wafer after the rough polishing is greater than the thickness of the carrier plate. Thereby, polishing of the carrier plate by the polishing cloths is inhibited and deterioration of the carrier plate can be prevented. Moreover, during the polishing process, vibration of the silicon wafer and the carrier plate can be inhibited and the silicon wafer can be prevented from jumping out of the carrier plate. A sun gear (epicyclic gear) system or a non-sun gear system which causes circular motion without inducing rotation in the carrier plate may be used as the double surface polishing device.

Finish polishing is preferably conducted on the polished surface of the rough-polished silicon wafer. Thereby, micro-roughness and haze can be reduced. Finish polishing means an operation in which the front surface of the wafer is mirror-surfaced in a final stage of the polishing operation for the silicon wafer. A suede-type pad in which urethane resin has been foamed onto a substrate fabric composed of a non-woven fabric may be used as the finish polishing cloth. In addition, a polishing agent in which free abrasive grains having an average particle size of around 20-100 nm have been added to the alkaline solution may be used as the finish polishing agent. The amount of finish polishing for the rough-polished surface of the silicon wafer is 0.1 μm or more and less than 1 μm.

The polishing solution of the present invention is a polishing solution used during rough polishing of at least a front surface of the front and rear surfaces of the silicon wafer as the polished surface. The chief component of the polishing solution of the present invention is the alkaline aqueous solution containing the free abrasive grains, to which the water-soluble polymer has been added. With such a polishing solution, roll-off on the outer periphery of the wafer can be prevented while maintaining a high polishing rate due to the etching effect of the alkaline aqueous solution, the abrasion effect of the free abrasive grains, and the etching inhibition effect of the water-soluble polymer on the outer periphery of the silicon wafer. In addition, conventional polishing methods use a polishing solution in which no water-soluble polymer is present despite including the free abrasive grains. As the polishing progresses, roll-off on the outer periphery of the wafer is promoted. In contrast, in the case of the present invention, due to the etching inhibition effect of the water-soluble polymer on the outer periphery of the silicon wafer described above, by having a long polishing time and increasing the polishing amount, for example, the outer periphery of the wafer can be made to have a roll-up shape. Thus, assuming roll-off on the outer periphery of the wafer during finish polishing, for example, an ideal flat shape can be achieved for the outer periphery of the wafer.

The content amount of an alkaline element in the alkaline aqueous solution is preferably set to 100-1000 ppm in the polishing solution. At less than 100 ppm, the etching force of the alkali on the front surface of the silicon wafer is insufficient and a long period of time is required to polish the silicon wafer to the desired thickness. At more than 1000 ppm, handling of the polishing solution itself becomes difficult and surface roughness is likely to occur in the front surface of the wafer due to an excessive etching reaction. The alkaline aqueous solution is preferably an alkaline aqueous solution to which any of a basic ammonium salt, a basic potassium salt, and a basic sodium salt has been added as the alkaline agent; an alkaline carbonate aqueous solution; or an alkaline aqueous solution to which amine has been added. In addition, the water-soluble polymer is preferably one kind or several kinds among a non-ionic polymer and a monomer, or one kind or several kinds among an anionic polymer and a monomer. Thereby, processing-induced defects such as scratches and flaws do not develop in the front surface of the silicon wafer, handling of the polishing solution is easy, and a high polishing (etching) rate can be obtained for the silicon wafer.

The concentration of the water-soluble polymer in the polishing solution is preferably set to a concentration range of 1-200 ppm. Daily management of the concentration of the water-soluble polymer in the polishing solution to a concentration range of less than 1 ppm is extremely difficult. When greater than 200 ppm, the polishing rate for the silicon wafer is greatly reduced. In addition, the outer periphery of the silicon wafer has excessive roll-up and the polishing amount in the finish polishing, which is performed after the rough polishing, must be dramatically increased.

Including hydroxyethylcellulose as the water-soluble polymer is particularly preferred. Highly pure hydroxyethylcellulose can be obtained comparatively easily and readily forms the polymer film on the front surface of the wafer. Thus, the effect of inhibiting the etching reaction from the alkali is characteristically high.

From the perspective of removing metallic ions contained in the polishing solution, adding a chelating agent to the polishing solution is preferred. By adding a chelating agent, metallic ions are captured and form complexes. By then disposing of these, a degree of metallic pollution of the silicon wafer after polishing can be reduced. Any substance having a chelating ability with respect to metallic ions may be used as the chelating agent. Chelating means bonding (coordination) with metallic ions due to a ligand having a plurality of coordinate positions.

The kinds of chelating agents that may be used are, for example, a phosphonic acid chelating agent, an aminocarboxylic acid chelating agent, or the like. However, when considering the solubility of the chelating agent in the alkaline aqueous solution, the aminocarboxylic acid chelating agent is preferred. Moreover, when considering the chelating ability with heavy metallic ions, aminocarboxylates such as ethylene diamine tetraacetic acid (EDTA) and diethylene triamine pentaacetic acid (DTPA) are more preferred. In addition, nitrilotriacetic acid (NTA) may also be used. The chelating agent is preferably added at a concentration range of 0.1 ppm-1000 ppm. Thereby, metallic ions such as Cu, Zn, Fe, Cr, Ni, and Al may be captured.

Hereafter, an embodiment of the present invention is specifically described. Herein, a method for manufacturing a double surface-polished silicon wafer and a polishing solution for the method are described in which the front surface and the rear surface are polished.

### Embodiment 1

A method for polishing a silicon wafer and a polishing solution for the method according to a first embodiment of the present invention are described. The first embodiment is configured so as to perform finish polishing after a first polishing, which is rough polishing. In the first polishing operation, the rough polishing is performed using a first polishing cloth and a polishing solution containing free abrasive grains and a water-soluble polymer. In the finish polishing operation, in order to achieve flattening of the silicon wafer, finish polishing is performed using a finish polishing cloth and a polishing solution containing free abrasive grains for finish polishing. A double surface-polished silicon wafer in which a front surface and a rear surface have been mirror polished is manufactured through each of the following operations. Specifically, a monocrystalline silicon ingot is pulled with the Czochralski method from a molten solution of silicon doped with a predetermined amount of boron in a crucible, the monocrystalline silicon ingot having a diameter of 306 mm, a straight trunk length of 2500 mm, a specific resistance of 0.01 Ω·cm, and an initial oxygen concentration of 1.0×10¹⁸ atoms/cm³.

Next, a monocrystalline silicon ingot is cut into a plurality of crystal blocks, and thereafter outer peripheral grinding is performed on each of the crystal blocks. Then, using a wire on three groove rollers arranged in a triangle, a large number of silicon wafers are sliced from the silicon monocrystal, the silicon wafers having a diameter of 300 mm and a thickness of 775 μm. Thereafter, a rotating chamfering grindstone is pressed against the outer periphery of the silicon wafer to chamfer the wafer, and next both surfaces of the silicon wafer are simultaneously lapped by a double surface lapping device. Next, the lapped silicon wafer is immersed in an acidic etching solution in an etching bath to be etched, thus removing damage from chamfering and lapping. After this, the first polishing and the finish polishing described above are conducted in sequence on the front and rear surfaces of the silicon wafer.

In the first polishing operation, a non-sun gear-type double surface polishing device is employed to simultaneously first polish the front and rear surfaces of the silicon wafer using a first polishing solution. The first polishing solution uses a piperidine aqueous solution (piperidine: 0.08% by weight) to which silica granules (free abrasive grains) from colloidal silica having an average particle size of 70 nm are added at 5% by weight and hydroxyethylcellulose (HEC: the water-soluble polymer) is added at 10 ppm.

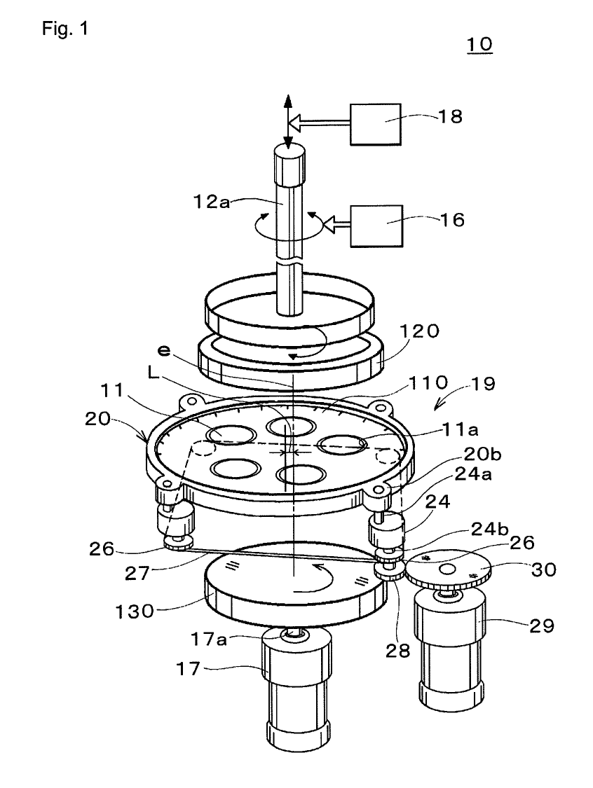

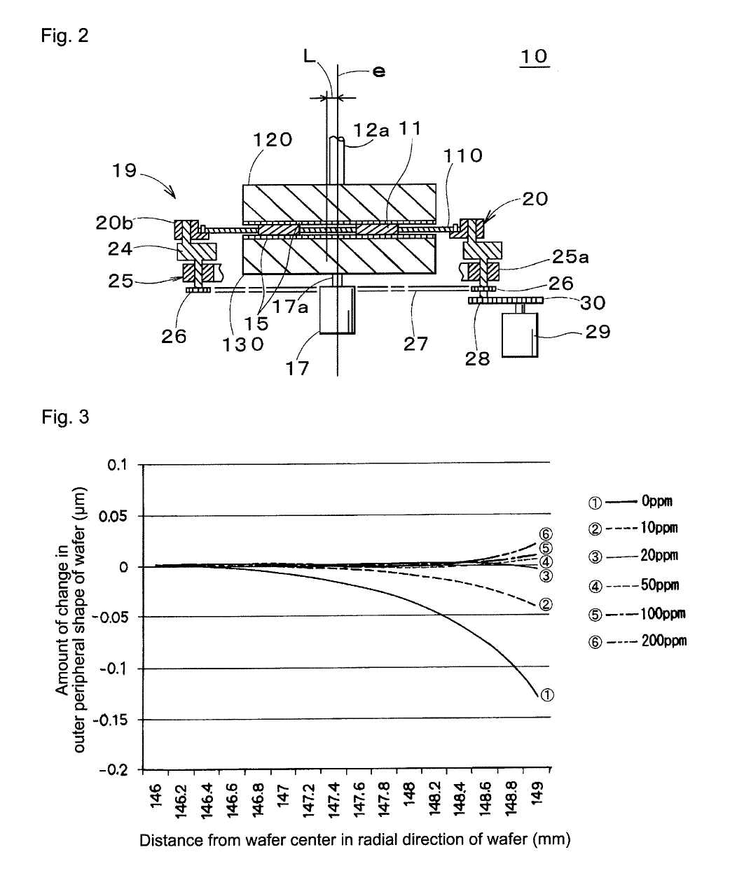

Hereafter, a non-sun gear-type double surface polishing device 10 is specifically described with reference to FIGS. 1 and 2. As shown in FIGS. 1 and 2, an upper platen 120 on the double surface polishing device 10 is rotationally driven within a horizontal plane by a top rotation motor 16 via a rotation shaft 12a that extends upward. The upper platen 120 is raised and lowered in a vertical direction by an elevating device 18, which advances and retreats in an axial line direction. The elevating device 18 is used when loading and unloading a silicon wafer 11 from a carrier plate 110, and the like. Moreover, a polishing force from the upper platen 120 and a lower platen 130 on the front and rear surfaces of the silicon wafer 11 is 300 g/cm², which is applied by a pressurizing means such as an air-backed system (not shown in the drawings) installed in the upper platen 120 and the lower platen 130. The lower platen 130 rotates within the horizontal plane due to a bottom rotation motor 17 via an output shaft 17a. The carrier plate 110 has a thickness of 725 μm and makes a circular motion within a plane (horizontal plane) parallel to the front surface of the plate 110 due to a carrier circular motion mechanism 19 such that the plate 110 does not rotate.

The carrier circular motion mechanism 19 includes an annular carrier holder 20 outwardly holding the carrier plate 110. The carrier circular motion mechanism 19 and the carrier holder 20 are connected via a connecting structure. Four outwardly projecting shaft receivers 20b are provided every 90° on the outer periphery of the carrier holder 20. A forefront of an eccentric shaft 24a is inserted into each of the shaft receivers 20b so as to be freely rotatable, the eccentric shafts 24a projecting at eccentric positions on a top surface of eccentric arms 24, which have a shape of a small diameter circular plate. At a central portion on a bottom surface of each of the four eccentric arms 24, a rotation shaft 24b is downwardly provided. Each of the rotation shafts 24b are inserted into a shaft receiver 25a so as to be freely rotatable, the foremost end of each rotation shaft 24b projecting downward from the shaft receiver 25a. A total of four shaft receivers 25a are provided every 90° on an annular device substrate 25. A sprocket 26 is affixed to the downward-projecting foremost end of each rotation shaft 24b. A timing chain 27 is passed in a loop around each of the sprockets 26 in a horizontal orientation. The four sprockets 26 and the timing chain 27 simultaneously rotate the four rotation shafts 24b such that the four eccentric arms 24 perform synchronized circular motion.

Of the four rotation shafts 24b, one of the rotation shafts 24b is formed to be even longer, the foremost end projecting downward past the sprocket 26. A drive force transmission gear 28 is affixed thereto. The gear 28 interlocks with a large diameter drive gear 30 that is affixed to an output shaft extending above a circular motion motor 29. Accordingly, when the circular motion motor 29 is activated, a rotation force thereof is transmitted to the timing chain 27 sequentially through the gears 30 and 28 and the sprocket 26 affixed to the long rotation shaft 24b. The timing chain 27 rotates epicyclically, and thereby, via the other three sprockets 26, the four eccentric arms 24 perform synchronized rotation in a horizontal plane centered on the rotation shafts 24b. Accordingly, the carrier holder 20, which is connected to each of the eccentric shafts 24a, and the carrier plate 110 held by the holder 20 perform circular motion in a horizontal plane parallel to the plate 110 without inducing rotation.

Specifically, the carrier plate 110 revolves while maintaining a state of eccentricity restricted to a distance L from an axial line e of the upper platen 120 and the lower platen 130. On each opposing face of the platens 120 and 130 is adhered a polishing cloth 15 made from foamed polyurethane having a Shore A hardness of 80 and a compression modulus of 2.5%. The distance L is the same as the distance between the eccentric shaft 24a and the rotation shaft 24b. All points on the carrier plate 110 trace a trajectory of a small circle having the same size (radius r) due to the circular motion that does not induce rotation. Thereby, the silicon wafer 11 accommodated in a wafer housing 11a formed on the carrier plate 110 undergoes the first polishing on both surfaces simultaneously with the polishing platens 120 and 130 being rotated in mutually opposite directions, such that the polishing amount is 5 μm per surface (10 μm for both surfaces) by adjusting the rotation speed of the polishing platens 120 and 130, the polishing pressure (300 g/cm²), and the polishing time.

During the first polishing of both surfaces, the first polishing process was performed by adjusting the polishing time such that the polishing amount would be 4.5-5.5 μm per surface (9-11 μm for front and rear surfaces) while supplying a first polishing solution to both of the polishing cloths 15 at 5 liters/minute. The first polishing solution includes silica grains from colloidal silica having an average particle size of 70 nm added at 5% by weight to 0.08% by weight of a piperidine aqueous solution, and contains 10 ppm of hydroxyethylcellulose. Moreover, when the polishing solution is used and the wafer holding method using the carrier plate 110 is employed in the first polishing, the carrier plate 110 vibrates due to the silicon wafer 11 shifting within the wafer housing 11a during polishing. Thus, there is a risk that the silicon wafer 11 may jump out of the wafer housing 11a during polishing. Therefore, in the first polishing the thickness of the silicon wafer 11 was greater than the thickness of the carrier plate 110, and the first polishing was concluded in this state.

In this way, a polishing solution to which the piperidine aqueous solution containing free abrasive grains had been added was used as the polishing solution for the first polishing. Therefore, natural oxide films of approximately 10 Å each on the front and rear surfaces of the silicon wafer 11 can be removed in a short amount of time chiefly with a mechanical effect of the abrasive grains. Moreover, after removing the natural oxide films from the front and rear surfaces, the silicon wafer 11 and the polishing cloths 15 are further rotated relative to each other to polish the front and rear surfaces of the silicon wafer 11 approximately 5 μm per surface. At this time, the polishing cloths 15 are pressed against the front and rear surfaces of the silicon wafer 11 due to an effect of the polishing pressure. Thereby, a film of the hydroxyethylcellulose in the polishing solution bonded to the front surface of the silicon wafer 11 is carried away from the polished surface of the silicon wafer 11 by the polishing cloth 15. As a result, polishing advances in a state where hydroxyethylcellulose is bonded to the outer periphery of the silicon wafer 11. Thus, the front and rear surfaces of the silicon wafer 11 are polished at a high polishing rate of 0.5 μm/min while maintaining a high degree of flatness due to an abrasion effect of the free abrasive grains, an etching effect of the alkaline aqueous solution, and an effect of removing hydroxyethylcellulose with the polishing cloth 15.

Meanwhile, on the outer periphery of the silicon wafer 11, adhesion of the polishing cloths 15 to an outer peripheral surface (chamfered surface) of the silicon wafer 11 is consistently inhibited during polishing by using the hard polishing cloth 15 made from foamed polyurethane. Thereby, the outer peripheral surface of the wafer is coated by the hydroxyethylcellulose in the polishing solution, which forms a protective film against etching on the outer peripheral surface of the wafer. As a result, the polishing rate decreases for a region up to 3 mm from the outer peripheral edge of the silicon wafer 11 and a decrease in roll-off on the outer periphery of the wafer can be achieved, as well as control over the degree of flatness of the outer periphery of the wafer that contains roll-off and roll-up. Moreover, the reason that a certain degree of roll-up development on the outer periphery of the wafer is acceptable is that during the finish polishing that follows, an offset may be anticipated in advance for the roll-off that occurs on the outer periphery of the silicon wafer 11. In contrast, in a case where a pliant polishing cloth made of suede is used as the polishing cloth for the first polishing, for example, the polishing cloths positioned above and below are in contact with the outer peripheral surface of the silicon wafer 11, and thus roll-off on the outer periphery of the silicon wafer 11 is promoted.

In addition, hydroxyethylcellulose is used as the water-soluble polymer. Therefore, an advantageous effect is obtained in which the polymer film is formed on the outer periphery of the silicon wafer 11 and the etching effect of the piperidine aqueous solution can be inhibited. In addition, the piperidine aqueous solution has an extremely high degree of purity and can achieve a reduction in pollution by impurities.

Moreover, the concentration of hydroxyethylcellulose in the finish polishing solution is 10 ppm. Therefore, processing-induced defects are not present on the front and rear surfaces of the silicon wafer 11. In addition, the silicon wafer 11, for which roll-off on the outer periphery of the wafer has been reduced, can be polished in a short amount of time. An alkaline aqueous solution in which the concentration of piperidine has been adjusted to 800 ppm was used as the alkaline aqueous solution. Therefore, processing-induced defects such as scratches and flaws in the front surface of the silicon wafer 11 do not develop, handling of the polishing solution is easy, and a high polishing rate can be obtained for the silicon wafer 11. In addition, a foamed polyurethane resin is employed as the material for both of the polishing cloths 15. Therefore, a reduction in the amount of roll-off at the outer periphery of the silicon wafer 11 can be achieved.

When an additive rate of hydroxyethylcellulose with respect to the polishing solution was changed to 0 ppm, 10 ppm, 20 ppm, 50 ppm, 100 ppm, and 200 ppm and the silicon wafer 11 was first polished according to other conditions of the first polishing as described above, variations in the outer peripheral shape of the silicon wafer 11 were investigated. The results are shown in the graph of FIG. 3. Moreover, in order to measure the shape of the outer periphery of the silicon wafer 11, a Wafer Sight manufactured by KLA-Tencor Corporation was used. In addition, in order to evaluate the shape of the outermost periphery of the silicon wafer 11, an ROA (Roll-Off Amount) was used which quantitatively expresses an amount of drop and an amount of rise in the outer periphery of the wafer.

An imaginary standard flat surface is obtained from the wafer shape at a position (reference area) 124 mm-135 mm from the center of the silicon wafer 11 having a diameter of 300 mm that is believed to be flat. “ROA 1 mm” is then defined as a distance from an outer edge of the wafer to a position 1 mm toward an interior. At this point, a height of the standard flat surface is defined as 0. When a shape up to the outer edge of the wafer drops below this, an amount of displacement has a −value (roll-off). When a shape rises instead, the amount of displacement has a +value (roll-up). In addition, the smaller the absolute value of the roll-off and roll-up, the higher the degree of flatness, even at the outermost periphery.

As made clear by the graph in FIG. 3, in the ROA 1 mm, when the additive rate of hydroxyethylcellulose in the polishing solution is 0 ppm, the amount of change in the outer peripheral shape of the wafer is −0.13 μm; when 10 ppm, −0.04 μm; when 20 ppm, approximately 0 μm; when 50 ppm, +0.01 mm; when 100 ppm, +0.015 μm; and when 200 ppm, +0.02 μm. Given the above, by adding hydroxyethylcellulose to the polishing solution, roll-off on the outer periphery of the wafer can be remedied. In particular, when 20 ppm is added, the front surface of the wafer becomes flat across substantially the entire surface. In addition, even when more than 20 ppm is added, a slight roll-up phenomenon occurred; however, a high flatness was observed to be maintained up to a vicinity of the outer peripheral edge of the wafer.

Moreover, as shown in Table 1, as the additive rate of hydroxyethylcellulose increased, the polishing time became longer and the polishing rate decreased. However, almost no change was identified in the polishing amount. In other words, the outer peripheral shape of the silicon wafer 11 was observed to not deteriorate even when the polishing time became longer.

TABLE 1

| | Polishing | Polishing | Polishing |
|---|---|---|---|
| Additive rate | Rate | Time | Amount |
| of HEC | [μm/min] | [min] | [μm] |
| 0 ppm | 0.43 | 25 | 10.75 |
| 10 ppm | 0.44 | 25 | 11 |
| 20 ppm | 0.41 | 25 | 10.25 |
| 50 ppm | 0.32 | 30 | 9.6 |
| 100 ppm | 0.24 | 40 | 9.6 |
| 200 ppm | 0.18 | 60 | 10.8 |

### INDUSTRIAL APPLICABILITY

The present invention is useful as a method for manufacturing with high productivity a silicon wafer having reduced roll-off on an outer periphery of the wafer.

### DESCRIPTION OF REFERENCE NUMERALS

10 double surface polishing device,
11 silicon wafer,
15 polishing cloth,
110 carrier plate,
120 upper platen,
130 lower platen.

1. A method for polishing a silicon wafer comprising:
rotating the silicon wafer and a hard polishing cloth relative to each other while a polishing solution is supplied to the polishing cloth to rough polish at least a front surface of the front and rear surfaces of the silicon wafer as a polished surface, the polishing solution having a water-soluble polymer added to an alkaline aqueous solution containing free abrasive grains.

2. The method for polishing the silicon wafer according to claim 1, wherein the water-soluble polymer is one kind or several kinds among a non-ionic polymer and a monomer, or one kind or several kinds among an anionic polymer and a monomer.

3. The method for polishing the silicon wafer according to claim 2, wherein the water-soluble polymer is hydroxyethylcellulose.

4. The method for polishing the silicon wafer according to claim 3, wherein a concentration of hydroxyethylcellulose in the polishing solution is 1 ppm-200 ppm.

5. The method for polishing the silicon wafer according to claim 1, wherein
a content amount of an alkaline agent in the alkaline aqueous solution is 100-1000 ppm; and
the alkaline aqueous solution is one of an alkaline aqueous solution to which any of a basic ammonium salt, a basic potassium salt, and a basic sodium salt has been added as the alkaline agent; an alkaline carbonate aqueous solution; and an alkaline aqueous solution to which amine has been added.

6. The method for polishing the silicon wafer according to claim 1, wherein the polishing cloth is composed of a non-woven fabric made from polyester, or is made from polyurethane.

7. The method for polishing the silicon wafer according to claim 1, wherein the rough polishing simultaneously polishes the front and rear surfaces of the silicon wafer with a double surface polishing device comprising:
a carrier plate accommodating the silicon wafer which has not yet been rough polished, and
an upper platen having the polishing cloth adhered to a bottom surface of the upper platen and a lower platen having a separate polishing cloth adhered to a top surface of the lower platen, the upper and lower platen sandwiching the carrier plate from above and below.

8. The method for polishing the silicon wafer according to claim 7, wherein the silicon wafer is polished such that a thickness of the silicon wafer after rough polishing is greater than the thickness of the carrier plate.

9. A polishing solution used during rough polishing at least a front surface of the front and rear surfaces of a silicon wafer as a polished surface, wherein
the polishing solution includes as a chief component an alkaline aqueous solution containing free abrasive grains and having a water-soluble polymer added to the alkaline aqueous solution.

10. The polishing solution according to claim 9, wherein:
a content amount of an alkaline agent in the alkaline aqueous solution is 100-1000 ppm;
the alkaline aqueous solution is one of an alkaline aqueous solution to which any of a basic ammonium salt, a basic potassium salt, and a basic sodium salt has been added as the alkaline agent; an alkaline carbonate aqueous solution; and an alkaline aqueous solution to which amine has been added; and
the water-soluble polymer is one kind or several kinds among a non-ionic polymer and a monomer, or one kind or several kinds among an anionic polymer and a monomer.

11. The polishing solution according to claim 10, wherein the water-soluble polymer is hydroxyethylcellulose.

12. The polishing solution according to claim 11, wherein a concentration of hydroxyethylcellulose in the alkaline aqueous solution is adjusted to be in a concentration range of 1 ppm-200 ppm.
